(19) United States
(12) Patent Application Publication
(10) Pub. No.: US 2024/0351953 A1
(43) Pub. Date: Oct. 24, 2024

(54) IMPREGNATION OF CERAMIC COMPOSITE MATERIAL

(71) Applicant: OULUN YLIOPISTO, Oulu (FI)

(72) Inventors: Yang BAI, Oulu (FI); Heli JANTUNEN, Oulu (FI); Jari JUUTI, Oulu (FI); Mikko NELO, Oulu (FI)

(21) Appl. No.: 18/688,129

(22) PCT Filed: Aug. 31, 2022
(86) PCT No.: PCT/FI2022/050563

§ 371 Date: Feb. 29, 2024

(30) Foreign Application Priority Data
Sep. 1, 2021 (FI) 20215914

(51) Int. Cl. C04B 35/491; C04B 35/626; C04B 35/628; C04B 35/64; C04B 41/00; C04B 41/45; C04B 41/50; C04B 41/87; H01B 3/12

(52) U.S. Cl. CPC C04B 35/491; C04B 35/62655; C04B 35/62675; C04B 35/62818; C04B 35/62886; C04B 35/64; C04B 41/0072; C04B 41/4515; C04B 41/4539; C04B 41/4554; C04B 41/5041; C04B 41/87; H01B 3/12; C04B 2235/3234; C04B 2235/3255; C04B 2235/5436; C04B 2235/5472; C04B 2235/604; C04B 2235/656

(57) ABSTRACT

A process for post-treatment of electroceramic composite material is disclosed. The process comprises introducing electroceramic composite material and flow-able organometallic compound to a pressure chamber, and degassing (1) the electroceramic composite material by creating a vacuum or underpressure in the pressure chamber, while the electroceramic composite material is immersed (2) in said organometallic compound. Then the pressure is elevated to an atmospheric pressure, wherein said flowable organometallic compound is absorbed (3) into at least part of the pores of the composite material. The electroceramic composite material containing said organometallic compound absorbed into said pores, is then treated (4) with water, water vapour and/or other chemical, thereby producing metal oxide impregnated electroceramic material containing solid metal oxide absorbed into said pores. Instead of flowable organometallic compound, a suspension of metal or metal oxide nanoparticles may be used for the post-treatment.

### FIELD OF THE INVENTION

The invention relates to electroceramic composite materials, and particularly to a method for post-treatment of electroceramic composite material by impregnation.

### BACKGROUND OF THE INVENTION

Electroceramics may be used in multitude of applications such as antennas, sensors, actuators and other passive components due to their unique properties such as pyro-, ferro-, or piezoelectricity or exceptional dielectric properties. Ceramic materials are used in a wide range of industries, including mining, aerospace, medicine, refinery, food and chemical industries, packaging science, electronics, industrial and transmission electricity, and guided lightwave transmission. Ceramic composite materials may be used for the manufacture of electronic components. Electronic components may be active components such as semiconductors or power sources, passive components such as resistors or capacitors, actuators such as piezoelectric or ferroelectric actuators, or optoelectronic components such as optical switches and/or attenuators. There is a pressure to improve the mechanical properties of the composites. Hence, there is a need to improve the ceramic material and its manufacture.

### SUMMARY

The following presents a simplified summary of features disclosed herein to provide a basic understanding of some exemplary aspects of the invention. This summary is not an extensive overview of the invention. It is not intended to identify key/critical elements of the invention or to delineate the scope of the invention. Its sole purpose is to present some concepts disclosed herein in a simplified form as a prelude to a more detailed description.

According to an aspect, there is provided the subject matter of the independent claims. Embodiments are defined in the dependent claims.

One or more examples of implementations are set forth in more detail in the description below. Other features will be apparent from the description, and from the claims.

### BRIEF DESCRIPTION OF THE DRAWINGS

In the following the invention will be described in greater detail by means of preferred embodiments with reference to the attached drawings, in which

FIG. 1 illustrates an exemplary post-treatment method;

FIGS. 2-7 illustrate obtained test results.

### DETAILED DESCRIPTION OF EMBODIMENTS

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments. Furthermore, words “comprising”, “containing” and “including” should be understood as not limiting the described embodiments to consist of only those features that have been mentioned and such embodiments may contain also features/structures that have not been specifically mentioned.

A recently developed solution to enhance the electrical properties and temperature resistance of the composites utilizes the combination of carefully selected particle size distribution of the filler material with liquid binder phase that can be turned into ceramic material. This enables a filler content of over 75 vol-%. The use of this method enables the manufacturing of all-ceramic piezoelectric materials at extremely low temperatures, with electrical performance comparable to materials produced with conventional sintering. Commonly, this composites manufacturing method results in composite materials with 10-15% remaining porosity. Reduction of this porosity even further would improve the performance of the composites.

The present invention discloses a post-processing method in which electroceramic composite pieces, such as discs or pellets, are impregnated with titanium isopropoxide solution, followed by hydrolysis of the organotitanate compound with water vapour to form titanium dioxide. The impregnation and hydrolysis treatment may be performed multiple times, with no limit for the number of composite samples impregnated at once, making the method an easy, cheap, and scalable way to improve the quality of electroceramic composites.

A post-treatment method is disclosed by means of which dielectric and mechanical properties of electroceramic composites are considerably improved.

The method comprises impregnation of electroceramic composite material by introducing liquid organometallic compound, such as titanium isopropoxide, into the pores contained in the composite. Further in the method, as a result of hydrolysis reactions, the organometallic compound impregnated into the pores is converted into a metal oxide with desired dielectric properties. For example, the relative density of ceramic composite treated with the method may increase by up to 5%, the relative permittivity of ceramic composite treated with the method may increase by up to 160%, the remanent polarization of lead zirconium titanate (PZT) may increase from 1.6 μC/cm² to 10 C/cm², and the remanent polarization of potassium sodium barium niobium nickel oxide (KNBNNO) may increase from about 2 μC/cm² to about 10 μC/cm². Also other dielectric properties, such as piezoelectric coefficient D33 and dielectric strength, may be significantly improved by the method.

Electroceramic composites prepared from KNBNNO or PZT, for example, may be post-treated by the method. In the post-treatment method, the properties of these composites may be improved by impregnating them with titanium isopropoxide and reacting the impregnated titanium isopropoxide with water to titanium dioxide. In the method, a clear improvement in both density and dielectric properties is achieved with these composite materials (KNBNNO, PZT).

The method enables to considerably improve the density and dielectric properties of various electroceramic composite materials in a simple and inexpensive manner at low temperatures. The method is usable for manufacturing all-ceramic composites, and it may be utilized with both new and recycled raw materials.

The method according to the present invention enables producing enhanced ceramic composite materials for electronics. During low-temperature manufacture of ceramic composite material, porosity of about 10-15% by volume, may remain in the finished parts, which impairs their electrical and mechanical properties. The method according to the present invention enables reducing or removing the porosity of the electroceramic composite material. In the method, this porosity is significantly reduced, whereby the dielectric and mechanical properties of the parts to be manufactured are significantly improved.

The invention enhances the method for making all-ceramic composite material. The method according to the invention solves a residual porosity problem of electroceramic composite material. The impregnation method of the invention reduces the porosity of ceramic-ceramic composite material, for example, for use as electrical components, by impregnating the ceramic-ceramic material by using, for example, flowable titanium isopropoxide.

An exemplary embodiment is based on the use of the organometallic-based impregnant to improve the properties of electroceramic composite material. The method disclosed herein enables improving dielectric properties. The method disclosed herein further enables improving mechanical properties with compaction. The method is simple, energy efficient, and produces minimal emissions.

The invention provides an enhanced method for manufacturing all-ceramic composites, in which a ceramic powder with a precisely controlled particle size distribution is mixed with a metal oxide-forming solution and compressed into an all-ceramic composite.

In the method all-ceramic composites are impregnated with an organo-metallic compound which fills the porosity contained in the composites as well as possible. Thus, the organometallic compound at least partly fills the pores. Then, the organometallic compound in the pores is reacted to form metal oxide, thereby significantly improving the dielectric and mechanical properties of the composite.

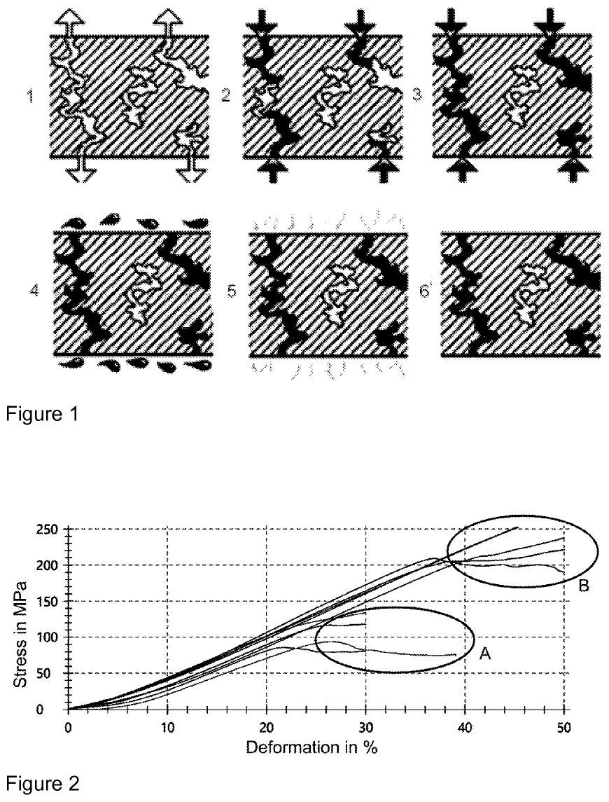

FIG. 1 illustrates an exemplary method where electroceramic composite material is densified by impregnation. In item 1, the electroceramic composite material is degassed by subjecting it to a vacuum or underpressure (e.g. an absolute pressure of 10 mbar-950 mbar, typically 200 mbar) in a container or pressure chamber. In item 2, flowable organometallic compound introduced to the pressure chamber is absorbed into the pores of the electroceramic composite, after the pressure is restored to normal (e.g. to an absolute pressure of about 1 bar). In item 3, overpressure (e.g. an absolute pressure of about 3 bar or above) may optionally be used to further enhance the penetration of the organometallic compound into the pores of the electroceramic composite. The overpressure to be selected may depend on the type of the container or pressure chamber used. In item 4, the composite may be removed from the pressure chamber, excess organometallic compound may be removed from the surface of the ceramic composite e.g. by wiping with a cloth, and the composite is treated with a chemical that causes the organometallic compound to react to form metal oxide. Examples of chemicals that may be used include water, water vapour and/or any other chemical capable of reacting with the flowable organometallic compound to form metal oxide. The metal oxide may be one or more of TiO₂ and aluminium oxide. In item 5, the composite is heated at 110° C.-130° C. for 1.5 h-2.5 h, typically at 120° C. for 2 h, to complete the reactions and to allow excess compounds exit from the composite by evaporation. After that, in item 6, a finalized impregnated electroceramic composite material is obtained. As shown in item 6, the method enables filling porosity which starts from the surfaces of the electroceramic composite. The porosity inside the electroceramic composite material, i.e. closed pores, remain.

The electroceramic composite part to be impregnated by the method, may be a part, such as a disc or pellet, prepared by obtaining an aqueous solution of the first ceramic by dissolving Li₂MoO₄ or other ceramic powder into water; obtaining a powder containing Li₂MoO₄ or said other ceramic precipitated on the surface of second ceramic particles by mixing second ceramic powder having a multi-modal particle size where largest particle size is above 50 μm and less than 180 μm, with the aqueous solution of the first ceramic; obtaining a powder mixture by mixing the powder containing Li₂MoO₄ or said other ceramic precipitated on the surface of the second ceramic particles, with the Li₂MoO₄ or said other ceramic powder having a particle size below 50 μm; obtaining an aqueous composition containing Li₂MoO₄ or said other ceramic, and the second ceramic, by adding saturated aqueous solution of Li₂MoO₄ or said other ceramic to the powder mixture; forming a disc or pellet of ceramic-ceramic composite material containing Li₂MoO₄ or said other ceramic, and the second ceramic, by compressing the aqueous composition in a mould; removing water from the ceramic-ceramic composite material by drying the disc; wherein the content of Li₂MoO₄ or said other ceramic is 10 vol-% to 35 vol-%, and the content of said second ceramic is above 65 vol-%, in the disc or pellet.

The electroceramic composite part to be impregnated by the method, may be a part that is bonded with an organometallic precursor material, by forming a combination of flowable metal oxide precursor which is water-insoluble, and electroceramic powder, for covering surfaces of electroceramic particles of the electroceramic powder with the metal oxide precursor, a major fraction of the particles having particle diameters within a range 50 μm to 200 μm, and a minor fraction of the particles having diameters smaller than the lower limit of said range, the major fraction having a variety of particle diameters. A pressure of 100 MPa to 500 MPa is applied to said combination. Said combination is exposed under the pressure to a heat treatment which has a maximum temperature within 100° C. to 500° C. for a predefined period for forming a disc or pellet of the electroceramic composite material.

In the beginning of the post-treatment process, the electroceramic composite part needs to be dry. Multiple ceramic composite parts may be impregnated at the same time. The ceramic composite part is immersed in flowable organometallic compound, for example, in a solution of titanium isopropoxide. The part is immersed in the solution during the impregnation. A vacuum/underpressure (e.g. an absolute pressure of 10 mbar-950 mbar, e.g. 200 mbar) is created into a container vessel containing the electroceramic part and the solution. A suitable underpressure is selected based on the flowable organometallic compound to be used, such that the pressure is above the boiling point of the flowable organometallic compound. Air exiting from the electroceramic part may be seen as bubbles in the solution. When no more bubbles are exiting from the electroceramic part, the vacuum/underpressure is removed. An overpressure may then be created into the container vessel (e.g. an absolute pressure of 3 bar or above). The overpressure enhances the penetration of the organometallic solution to the pores of the electroceramic part. The overpressure may be maintained e.g. for 10 minutes. The part is then removed from the container, i.e. the part is then no longer immersed in the titanium isopropoxide solution. Excess titanium isopropoxide solution is wiped from the surface of the part. The part from which excess titanium isopropoxide solution has been removed by wiping, is immersed in water, or treated with steam (water vapour) (or other suitable chemical) for 1-15 min. The water reacts with titanium isopropoxide in the pores of the part to form solid titanium dioxide and alcohol (propanol). The part is introduced e.g. into an oven where liquid reaction products (alcohol) and excess water are evaporated from the part by using heat (e.g. 125° C. for 2 hours). The impregnated electroceramic part is then ready for use. The post-treatment process may be repeated several times for the part; the density typically increasing up to five consecutive impregnation cycles.

The method enables a significant improvement in dielectric properties of KNBNNO and/or PZT all-ceramic composites, as well as an increase in relative density. In addition, the surfaces of the post-treated parts became much tighter and more durable.

In an embodiment, post-impregnation of ceramic composite may also be performed with liquid compounds other than the above organotitanate. The requirement is that the compound is liquid and, after impregnation, it may be reacted into a solid metal oxide having desired dielectric properties. Thus, for example, mixtures of several different organometallic compounds may be used which are finally reacted into metal oxides or metal oxides which dissolve in a suitable solvent which evaporates after the treatment.

In an embodiment, as metal oxides, a suspension of nanoparticles may also be used, wherein the suspension is absorbed into the part, and the solvent is then evaporated from the part. The nanoparticles may be either desired metal oxide nanoparticles or metal particles that oxidize to form the desired metal oxide after removal of the solvent. The electroceramic composite material and suspension of metal or metal oxide nanoparticles are introduced to a pressure chamber. The electroceramic composite material is degassed by creating a vacuum or underpressure in the pressure chamber, the electroceramic composite material being immersed in said suspension of metal or metal oxide nanoparticles in the pressure chamber. The pressure in the pressure chamber is then elevated to an atmospheric pressure, wherein said suspension of metal or metal oxide nanoparticles is absorbed into at least part of the pores of the degassed electroceramic composite material. The electroceramic composite material containing said suspension of metal or metal oxide nanoparticles absorbed into said pores, is then treated with water, water vapour and/or other chemical capable of interacting with the said suspension of metal or metal oxide nanoparticles to produce solid metal oxide, thereby forming metal oxide impregnated electroceramic material containing solid metal oxide absorbed into said pores. The metal or metal oxide is one or more of Ti, Al, TiO₂, and aluminium oxide.

The present invention may be carried out with a large number of composite parts at once by selecting the impregnation vessel/pressure chamber of suitable size (i.e. large enough).

In an embodiment, the process for post-treatment of electroceramic composite material, comprises introducing electroceramic composite material and flowable organometallic compound to a pressure chamber, degassing the electroceramic composite material by creating a vacuum or underpressure in the pressure chamber, the electroceramic composite material being immersed in said flowable organometallic compound in the pressure chamber, elevating the pressure in the pressure chamber to an atmospheric pressure, wherein said flowable organometallic compound is absorbed into at least part of the pores of the degassed electroceramic composite material, and treating the electroceramic composite material containing said flowable organometallic compound absorbed into said pores, with water, water vapour and/or other chemical capable of reacting with said flowable organometallic compound to form solid metal oxide, thereby forming metal oxide impregnated electroceramic material containing solid metal oxide absorbed into said pores.

In an embodiment, the organometallic compound is liquid titanium isopropoxide, liquid titanium butoxide, or other flowable organotitanate, or a mixture thereof, preferably liquid titanium isopropoxide.

In an embodiment, the process for post-treatment of electroceramic composite material, comprises introducing electroceramic composite material and suspension of metal or metal oxide nanoparticles to a pressure chamber, degassing the electroceramic composite material by creating a vacuum or underpressure in the pressure chamber, the electroceramic composite material being immersed in said suspension of metal or metal oxide nanoparticles in the pressure chamber, elevating the pressure in the pressure chamber to an atmospheric pressure, wherein said suspension of metal or metal oxide nanoparticles is absorbed into at least part of the pores of the degassed electroceramic composite material, and heat-treating the electroceramic composite material containing said suspension of metal or metal oxide nanoparticles absorbed into said pores, at a temperature of 100 to 350° C., to produce solid metal oxide, thereby producing metal oxide impregnated electroceramic material containing solid metal oxide absorbed into said pores. Additionally, the electroceramic composite material containing said suspension of metal or metal oxide nanoparticles absorbed into said pores, may be treated with water, water vapour and/or other chemical capable of interacting with the said suspension of metal or metal oxide nanoparticles to produce solid metal oxide.

In an embodiment, the method comprises drying the metal oxide impregnated electroceramic composite material by heating. The drying of the metal oxide impregnated electroceramic composite material may be carried out at 110° C.-130° C. for 1.5 h-2.5 h, preferably at 120° C. for 2 h.

In an embodiment, the underpressure is an absolute pressure of 10 mbar-950 mbar, preferably 200 mbar.

In an embodiment, the electroceramic composite material containing said flowable organometallic compound or said suspension of metal or metal oxide nanoparticles absorbed into said pores is subjected to overpressure before the treatment with water, water vapour and/or said other chemical, to enhance penetration of the organometallic compound or the metal or metal oxide nanoparticles into said pores of the electroceramic composite material, wherein the overpressure preferably is an absolute pressure of about 3 bar or above, wherein the electroceramic composite material is preferably subjected to the overpressure for 2-10 min.

In an embodiment, the metal or metal oxide is one or more of Ti, Al, TiO₂, Al₂O₃, Ba, BaO, Ni, NiO, Zn, ZnO, Bi, and Bi₂O₃, preferably one or more of Ti, Ba, TiO₂, and BaO.

In an embodiment, before the treatment with water, water vapour and/or said other chemical, excess flowable organometallic compound or suspension of metal or metal oxide nanoparticles is removed from the surface of the electroceramic composite, preferably by wiping.

In an embodiment, the electroceramic composite material contains first ceramic and second ceramic and is obtainable by obtaining an aqueous solution of the first ceramic by dissolving first ceramic powder into water, obtaining a powder containing said first ceramic precipitated on the surface of second ceramic particles by mixing second ceramic powder having a multimodal particle size where largest particle size is above 50 μm and less than 180 μm, with the aqueous solution of the first ceramic, obtaining a powder mixture by mixing the powder containing said first ceramic precipitated on the surface of the second ceramic particles, with the said first ceramic powder having a particle size below 50 μm, obtaining an aqueous composition containing said first ceramic, and the second ceramic, by adding saturated aqueous solution of said first ceramic to the powder mixture, forming a disc or pellet of the electroceramic composite material containing said first ceramic, and the second ceramic, by compressing the aqueous composition in a mould, and removing water from the electroceramic composite material by drying said disc or pellet. The content of said first ceramic is 10 vol-% to 35 vol-%, and the content of said second ceramic is above 65 vol-%, in said disc or pellet. The compressing of the aqueous composition may be performed by using a moulding pressure of 100 to 500 MPa, preferably 250 MPa. The disc may be dried for at least 16 h at a temperature from 20° C. to 120° C., preferably for 16 h at a temperature of 120° C.

In an embodiment, the electroceramic composite material contains first ceramic and second ceramic, wherein the first ceramic is at least one of Li₂MoO₄, Na₂Mo₂O₇, K₂Mo₂O₇, (LiBi)_{0.5}MoO₄, Li₂WO₄, Mg₂P₂O₇, and V₂O₅, and the second ceramic is at least one of PZT, BaₓSr₁₋ₓTiO₃, TiO₂, Al₂O₃, KNBNNO, ferrite ceramic material, and other electroceramic material.

In an embodiment, the electroceramic composite material is obtainable by forming a combination of flowable metal oxide precursor which is water-insoluble, and electroceramic powder, for covering surfaces of electroceramic particles of the electroceramic powder with the metal oxide precursor, a major fraction of the particles having particle diameters within a range 50 μm to 200 μm, and a minor fraction of the particles having diameters smaller than the lower limit of said range, the major fraction having a variety of particle diameters, applying pressure 100 MPa to 500 MPa to said combination, and exposing said combination under the pressure to a heat treatment which has a maximum temperature within 100° C. to 500° C. for a predefined period for forming a disc or pellet of the electroceramic composite material. The flowable metal oxide precursor may be a precursor producing at least one of TiOₓ, and BaOₓ. The electroceramic powder may include at least one of PZT, KNBNNO, TiO₂, titanate material, and perovskite material.

In an embodiment, a post-treated electroceramic composite material prepared by the post-treatment process, is provided.

In an embodiment, an electronic component comprising the post-treated electroceramic composite material, is provided.

In an embodiment, the electronic component comprises at least one of a resistor, conductor and capacitor.

In an embodiment, the post-treated electroceramic composite material is used in electronic components including one or more of a resistor, capacitor, coil, sensor, actuator, high frequency passive device, energy storage and harvesting, tuning element, and transformer.

In an embodiment, an electronic product comprising the electronic component, is provided.

### Example

The method to improve the electrical properties of all-ceramic composites for electronics applications by post-treatment, was tested by impregnation of composite samples with titanium isopropoxide solution, followed by a hydrolysis step and a drying step at 120° C. The d33 piezoelectric charge coefficient of the impregnated samples was measured to improve around 15% with the treatment, to 180 pC/N 24 hours after poling, outperforming other low-temperature piezoelectric composites. In addition to this, the compressive strength of the composite material was doubled with the post-treatment.

The testing of the impregnation method was carried out to composite samples based on two different ceramic materials, KNBNNO ((K,Na,Ba) (Ni,Nb)O3-δ) and PZT. PZT powder used was commercial lead zirconate titanate powder (type PZ29, Meggit Ferroperm-piezoceramics, Denmark) collected with 63-180 μm screens, whereas KNBNNO was synthesized in-house. The titanium isopropoxide used in the impregnation tests was a solution of 95 wt-% Ti-iPr4 in isopropyl alcohol.

10 mm diameter composite pellets were submerged to titanium isopropoxide solution in a 10 mL glass bottle. The pressure inside the bottle was reduced to 200 mbar for 15 minutes to remove air from the porosity inside the pellets. Then, while keeping the pellets submerged in titanium isopropoxide, the pressure inside the bottle was increased to 3 bars for two minutes to fill the pores of the composite with titanium isopropoxide. After the impregnation, the pellets were held in water vapour for 15 minutes to cause the titanium isopropoxide to react into titanium dioxide. Finally, the pellets were dried in an oven at 125° C. for two hours. After drying, the impregnated samples were weighed with a precision balance. The impregnation or post-treatment sequence including the impregnation treatment, the water vapour treatment and the drying in the oven was repeated up to 5 times.

The mechanical characterization of impregnated and unimpregnated pellets was carried out according to test standard ASTM D 695, utilizing Zwick Z030 compressive strength tester device. The samples to be measured were impregnated five times to achieve a saturation point in the absorption of the titanium isopropoxide solution.

The microstructure of the composite was assessed using field emission scanning electron microscopy (FESEM, Zeiss Sigma, Carl Zeiss SMT AG) on cross-sectioned and polished specimens. Before FESEM analysis, a thin layer of carbon was sputtered on the polished surface to avoid charging effects.

Dielectric properties at room-temperature were measured with a LCR meter (Hewlett-Packard 4284A, Agilent Technologies, USA). For dielectric and ferroelectric measurements, thick film silver ink electrodes were screen printed (DuPont 5064H, DuPont Microcircuit Materials, Research Triangle Park, NC) on both sides of the discs and cured at 120° C. for 20 minutes. Ferroelectric measurements (up to 6 kV/mm electric field) were performed at room temperature using a ferroelectric tester (Precision 10kV HVI-SC, Radiant Tech., USA). The waveform used in the measurements was a standard bipolar triangle at a frequency of 1-100 Hz. The breakdown electric fields were tested to be 4 kV/mm and 6 kV/mm for the PZT and KNBNNO samples, respectively. The leakage current and large-signal resistivity were also measured with the same ferroelectric tester. As a comparison, a commercial PZ29 disc shaped sample (Meggitt Ferroperm-piezoceramics, Denmark) was also analyzed with the ferroelectric tester. The samples were poled at a 4 kV/mm electric field for 30 minutes at room temperature and in silicone oil. After poling, the samples were shorted for 24 hours before the measurement. The piezoelectric coefficient d33 was then measured using a Berlincourt d33-meter (YE2730A, APC International, Ltd., USA). The sample was clamped between cone shaped probes and an alternating force of 0.25 N at 110 Hz was applied.

The mechanical properties of the samples increased greatly with the impregnation steps. FIG. 2 shows stress vs. deformation in unimpregnated (lower oval) and impregnated (upper oval) samples. The stress required for sample deformation increased over 100% with impregnation of the samples.

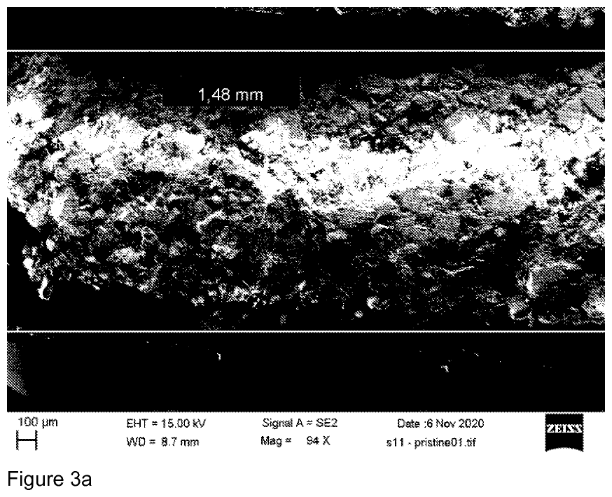

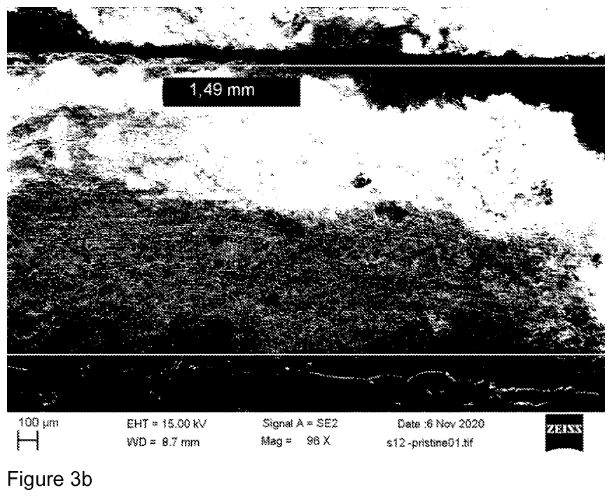

The structure of the composite samples was observed by scanning electron microscopy analysis of cross-sectioned composites (FIGS. 3a and 3b). The microstructure showed a uniform distribution of large PZT particles with a close proximity and surrounded by TiO₂ phase. The composition was measured to be 75-80 vol-% PZT, 5-8 vol. % TiO₂ and 12-15 vol-% voids.

In FIGS. 3a and 3b, the horizontal lines show the measurement range for the samples used for elemental analysis. Elements other than Pb, Zr and Ti were discarded in FESEM-EDS analysis just to focus on PZT and TiO₂ concentration. 30 line scans were performed horizontally with 50 μm gaps between lines on samples that were 1.5 mm thick. FIGS. 3a and 3b show the measured area marked between the white lines. 500 measurement points per line were measured. Every point was measured 10 times to increase accuracy. In FIGS. 3a and 3b, each measurement point gives the average composition of one line scan, i.e. 500 points each measured 10 times. As large surface area as possible was used in elemental analysis, in order to achieve as representative sample as possible.

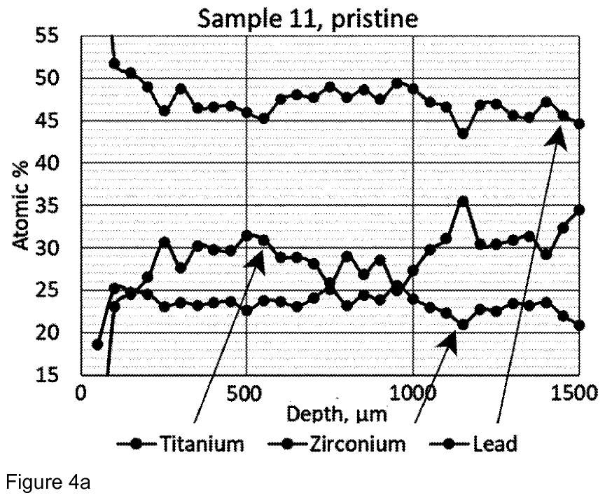

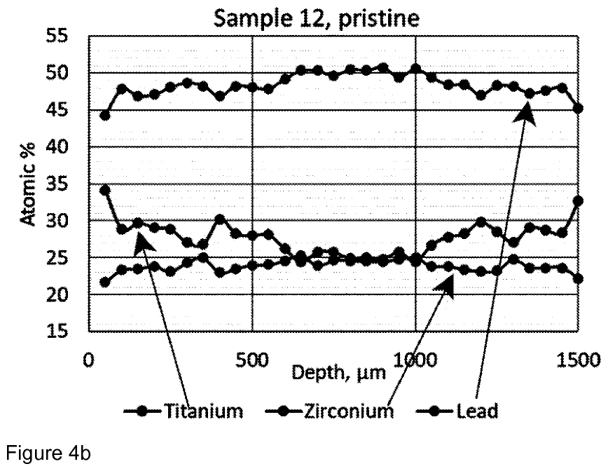

FIGS. 4a and 4b show elemental composition of unimpregnated (sample 11, FIG. 4a) and impregnated (sample 12, FIG. 4b) samples. The titanium content on the surface increased with impregnation.

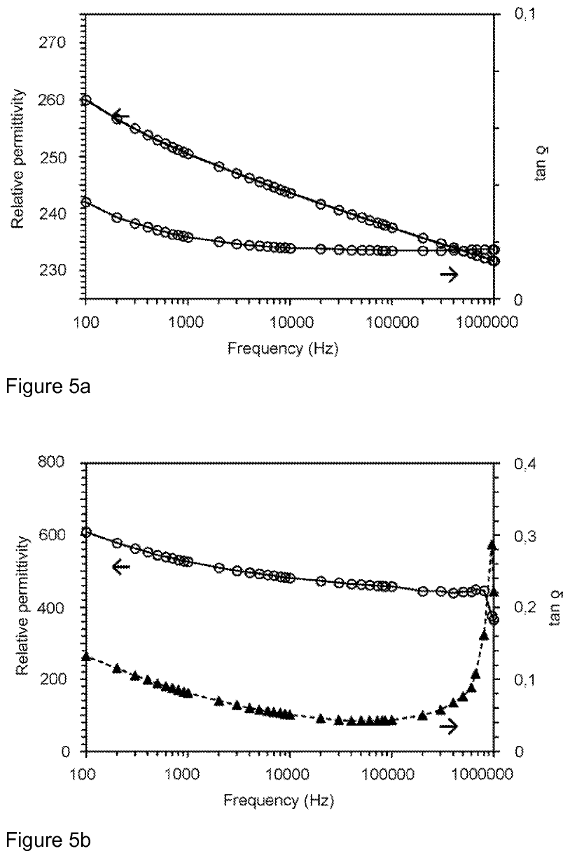

The relative permittivity (εᵣ) and the dielectric loss tangent (tan δ) measured between 100 Hz and 1 MHz increased with impregnation of the samples from ˜ 230-260 to 450-600 and from 0.10-0.02 to 0.05 to 0.3, respectively. FIGS. 5a and 5b show permittivity and losses of typical impregnated (FIG. 5b) and unimpregnated (FIG. 5a) samples at frequencies between 100 Hz and 1 MHz. FIGS. 5a and 5b show that both relative permittivity and loss tangent values were greatly increased with impregnation treatment.

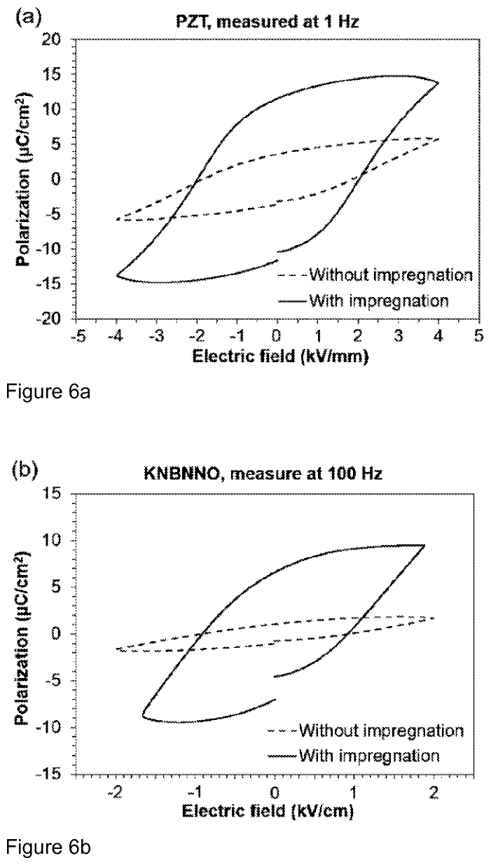

FIGS. 6a and 6b compare the ferroelectric hysteresis (P-E) loops of the samples with and without the impregnation treatment. For the PZT samples, it can be seen in FIG. 6a that both the P-E loops saturated with the maximum electric field of 4 kV/mm without noticeable lossy behaviour caused by increased leakage. The large-field resistivities of both the samples were measured to be >1 GΩ·cm, a value that is comparable to most good ferroelectric ceramics, ensuring a good insulation required for the P-E loop measurement. The remanent polarization was boosted from 3-4 μC/cm² to >10 μC/cm² which is an approximately 300% improvement. FIGS. 6a and 6b show the dependence of polarization on electric field for the (FIG. 6a) PZT and (FIG. 6b) KNBNNO ceramic composite samples with and without impregnation treatments.

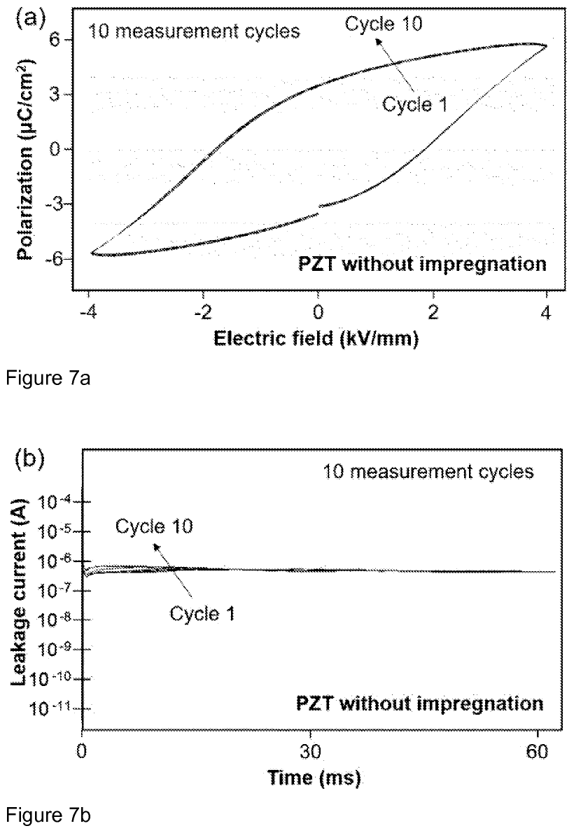

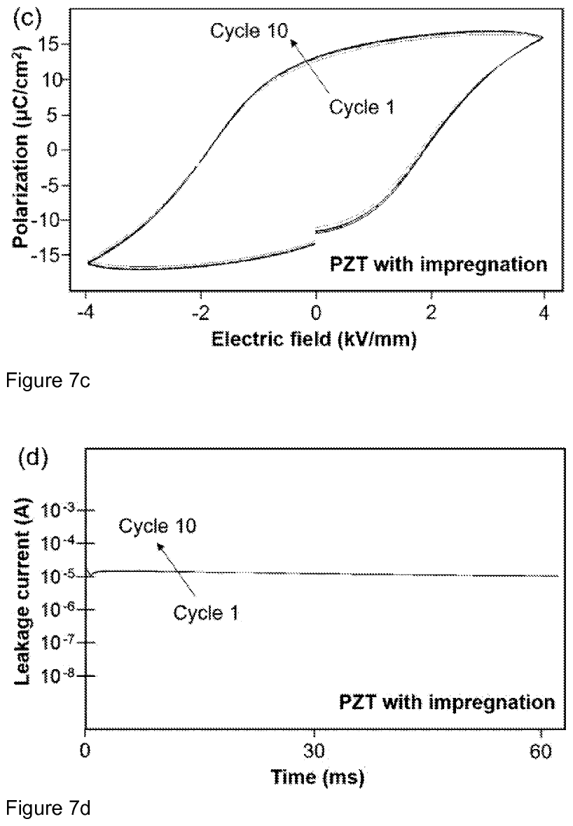

The reliability of the phenomenon is proved in FIGS. 7a, 7b, 7c and 7d in which the P-E loops for both the PZT samples with and without the impregnation treatment were repeatably measured. No change was noticed for the P-E loops and leakage currents during the 10 consecutive measurements, indicating that the samples were electrically stable. FIGS. 7a and 7c show ferroelectric hysteresis loops and FIGS. 7b and 7d show leakage currents with 4 kV/mm electric field measured for 10 cycles consecutively for PZT samples (FIGS. 7a and 7b) without and (FIGS. 7c and 7d) with the impregnation treatment.

The d33 value of the PZT samples with the impregnation treatment was measured to be about 180 pC/N, compared to about 150 pC/N for the samples without the impregnation treatment.

In order to evaluate whether the impregnation treatment method is potentially transferrable to other ferroelectric compositions, the in-house made KNBNNO ceramics were treated in the same way as was for the PZT samples. A similar boosting phenomenon of the ferroelectric properties is seen in FIG. 6b. Before the treatment, the KNBNNO showed negligible maximum and remanent polarizations, while a >700% improvement was observed after the treatment. Thus the impregnation treatment method is versatile and usable with various ferroelectric and piezoelectric ceramics.

Thus the method improved the dielectric and electromechanical properties of the electroceramic composite materials (see Table 1). The method greatly improved the relative density of the composite, leading to improved electric performance. A typical increase in the dielectric constant was around 25-30%, whereas the d33 piezoelectric charge coefficient was measured to improve around 15%, to 180 pC/N, outperforming other low-temperature piezoelectric composites. In addition to this, the compressive strength of the material was doubled with the treatment.

TABLE 1
Comparison of electromechanical properties of impregnated
and non-impregnated TiO₂ composites fabricated at 350° C.

| Property | Non-impregnated | Impregnated |
|---|---|---|
| density (g/cm³) | 5.87 | 6 |
| εᵣ at 1 kHz | 278 | 527 |
| tanδ at 1 kHz | 0.021 | 0.081 |
| Pᵣ (μC/mm²) | 0.083 | 11 |
| d₃₃² (pC/N) | 151 | 180 |
| g₃₃³ (mVm/N) | 59 | 41 |

It will be obvious to a person skilled in the art that, as the technology advances, the inventive concept can be implemented in various ways. The invention and its embodiments are not limited to the examples described above but may vary within the scope of the claims.

1. A process for post-treatment of electroceramic composite material, the process comprising
introducing electroceramic composite material and flowable organometallic compound to a pressure chamber;
degassing the electroceramic composite material by creating a vacuum or underpressure in the pressure chamber, the electroceramic composite material being immersed in said flowable organometallic compound in the pressure chamber;
elevating the pressure in the pressure chamber to an atmospheric pressure, wherein said flowable organometallic compound is absorbed into at least part of the pores of the degassed electroceramic composite material; and
treating the electroceramic composite material containing said flowable organometallic compound absorbed into said pores, with water, water vapour and/or other chemical capable of reacting with said flowable organometallic compound to form solid metal oxide, thereby producing metal oxide impregnated electroceramic material containing solid metal oxide absorbed into said pores.

2. A process according to claim 1, wherein the organometallic compound is liquid titanium isopropoxide, liquid titanium butoxide, or other flowable organotitanate, or a mixture thereof, preferably liquid titanium isopropoxide.

3. A process for post-treatment of electroceramic composite material, the process comprising
introducing electroceramic composite material and suspension of metal or metal oxide nanoparticles to a pressure chamber;
degassing the electroceramic composite material by creating a vacuum or underpressure in the pressure chamber, the electroceramic composite material being immersed in said suspension of metal or metal oxide nanoparticles in the pressure chamber;
elevating the pressure in the pressure chamber to an atmospheric pressure, wherein said suspension of metal or metal oxide nanoparticles is absorbed into at least part of the pores of the degassed electroceramic composite material; and
heat-treating the electroceramic composite material containing said suspension of metal or metal oxide nanoparticles absorbed into said pores, at a temperature of 100 to 350° C. to produce solid metal oxide, thereby producing metal oxide impregnated electroceramic material containing solid metal oxide absorbed into said pores.

4. A process according to claim 3, wherein the method comprises treating the electroceramic composite material containing said suspension of metal or metal oxide nanoparticles absorbed into said pores, with water, water vapour and/or other chemical capable of interacting with the said suspension of metal or metal oxide nanoparticles to produce solid metal oxide.

5. A process according to claim 1, wherein the method comprises drying the metal oxide impregnated electroceramic composite material by heating, wherein the drying of the metal oxide impregnated electroceramic composite material is preferably carried out at 110° C.-130° C. for 1.5 h-2.5 h, more preferably at 120° C. for 2 h.

6. A process according to claim 1, wherein
the underpressure is an absolute pressure of 10 mbar-950 mbar, preferably 200 mbar.

7. A process according to claim 1, wherein the electroceramic composite material containing said flowable organometallic compound or said suspension of metal or metal oxide nanoparticles absorbed into said pores is subjected to overpressure before the treatment with water, water vapour and/or said other chemical, to enhance penetration of the organometallic compound or the metal or metal oxide nanoparticles into said pores of the electroceramic composite material, wherein the overpressure preferably is an absolute pressure of about 3 bar or above, wherein the electroceramic composite material is preferably subjected to the overpressure for 2-10 min.

8. A process according to claim 1, wherein the metal or metal oxide is one or more of Ti, Al, TiO₂, Al₂O₃, Ba, BaO, Ni, NiO, Zn, ZnO, Bi, and Bi₂O₃, preferably one or more of Ti, Ba, TiO₂, and BaO.

9. A process according to claim 1, wherein before the treatment with water, water vapour and/or said other chemical, excess flowable organometallic compound or suspension of metal or metal oxide nanoparticles is removed from the surface of the electroceramic composite, preferably by wiping.

10. A process according to claim 1, wherein the electroceramic composite material contains first ceramic and second ceramic and is obtainable by
obtaining an aqueous solution of the first ceramic by dissolving first ceramic powder into water;
obtaining a powder containing said first ceramic precipitated on the surface of second ceramic particles by mixing second ceramic powder having a multimodal particle size where largest particle size is above 50 μm and less than 180 μm, with the aqueous solution of the first ceramic;
obtaining a powder mixture by mixing the powder containing said first ceramic precipitated on the surface of the second ceramic particles, with the said first ceramic powder having a particle size below 50 μm;
obtaining an aqueous composition containing said first ceramic, and the second ceramic, by adding saturated aqueous solution of said first ceramic to the powder mixture;
forming a disc or pellet of the electroceramic composite material containing said first ceramic, and the second ceramic, by compressing the aqueous composition in a mould;
removing water from the electroceramic composite material by drying said disc or pellet;
wherein the content of said first ceramic is 10 vol-% to 35 vol-%, and the content of said second ceramic is above 65 vol-%, in said disc or pellet.

11. A process according to claim 10, wherein the compressing of the aqueous composition is performed by using a moulding pressure of 100 to 500 MPa, preferably 250 MPa.

12. A process according to claim 10, wherein the disc is dried for at least 16 h at a temperature from 20° C. to 120° C., preferably for 16 h at a temperature of 120° C.

13. A process according to claim 10, wherein the first ceramic is at least one of Li₂MoO₄, Na₂Mo₂O₇, K₂Mo₂O₇, (LiBi)_{0.5}MoO₄, Li₂WO₄, Mg₂P₂O₇, and V₂O₅, and the second ceramic is at least one of PZT, BaₓSr₁₋ₓTiO₃, TiO₂, Al₂O₃, KNBNNO, ferrite ceramic material, and other electroceramic material.

14. A process according to claim 1, wherein the electroceramic composite material is obtainable by
forming a combination of flowable metal oxide precursor which is water-insoluble, and electroceramic powder, for covering surfaces of electroceramic particles of the electroceramic powder with the metal oxide precursor, a major fraction of the particles having particle diameters within a range 50 μm to 200 μm, and a minor fraction of the particles having diameters smaller than the lower limit of said range, the major fraction having a variety of particle diameters;
applying a pressure of 100 MPa to 500 MPa to said combination;
exposing said combination under the pressure to a heat treatment which has a maximum temperature within 100° C. to 500° C. for a predefined period for forming a disc or pellet of the electroceramic composite material.

15. A process according to claim 14, wherein the electroceramic powder includes at least one of PZT, KNBNNO, TiO₂, titanate material, and perovskite material.

16. A post-treated electroceramic composite material prepared by the process of claim 1.

17. An electronic component comprising the post-treated electroceramic composite material of claim 16.

18. An electronic component according to claim 17, wherein the electronic component comprises at least one of a resistor, conductor and capacitor.

19. Use of the post-treated electroceramic composite material of claim 16 in electronic components including one or more of a resistor, capacitor, coil, sensor, actuator, high frequency passive device, energy storage and harvesting, tuning element, and transformer.

20. An electronic product comprising the electronic component of claim 17.
